(19) United States
(12) Patent Application Publication
(10) Pub. No.: US 2016/0064254 A1
(43) Pub. Date: Mar. 3, 2016

(54) HIGH DENSITY IC PACKAGE

(71) Applicant: Dyi-Chung HU, Hsinchu County (TW)

(72) Inventor: Dyi-Chung HU, Hsinchu County (TW)

(21) Appl. No.: 14/469,850

(22) Filed: Aug. 27, 2014

(51) Int. Cl. H01L 21/48; H01L 23/498

(52) U.S. Cl. CPC H01L 21/4846; H01L 21/486; H01L 23/49827; H01L 23/49811; H01L 23/498

(57) ABSTRACT

The present invention discloses a high density IC package with a core substrate. The core substrate has four lateral sides; each lateral side extends to and flushes with a corresponding lateral side of the package. Further, a bottom first redistribution circuit following IC design rule or TFTLCD design rule is fabricated on a bottom side of the core substrate, and a bottom second redistribution circuit following PCB design rule is fabricated on a bottom side of the first redistribution circuit.

### BACKGROUND

1. Technical Field

The present invention relates to a high density IC package, especially relates to an IC package with a core substrate having four lateral sides extended to each side edge of the IC package. For a first embodiment, a top redistribution circuit is configured on a top side of the core substrate and a bottom first redistribution circuit is configured on a bottom side of the core substrate.

The core substrate used in the present invention can be either organic or inorganic. For organic substrates, one of Polyimide (PI), Polybenzoxazole (PBO), and Benzocyclobuten (BCB) substrates can be used according to the present invention. For inorganic substrates, one of glass, ceramic, or silicon substrates can be used according to the present invention.

For a second embodiment, a bottom second redistribution circuit is configured on a bottom side of the bottom first redistribution circuit. Where, the bottom first redistribution circuit is fabricated following IC design rule or TFTLCD Process design rule, and the bottom second redistribution circuit is fabricated following PCB Process design rule.

2. Description of Related Art

FIG. 1A shows a prior art IC package

FIG. 1A shows a prior art IC package disclosed in US2014/0102777A1 which has an embedded interposer 20. The interposer 20 has four later sides 206. A molding layer 22 wraps the interposer 20 around the four later sides 206 of the interposer 20. A plurality of via metal 200 is made through the interposer 20. An insulation liner 201 is made between the through via 200 and the interposer 20 for an electrical insulation there-between. A top redistribution layer 21 is made on a top side of the interposer 20 with a plurality of metal pad 210 exposed on a top side. The plurality of metal pad 210 on a top side is provided for an IC chip 3 or additional chips to mount. A circuit built-up structure 25 is made on a bottom side of the interposer 20 with a plurality of metal pad 220 configured on a bottom side. A plurality of solder ball 4 is configured on a bottom side of each bottom metal pad 220 of the bottom built-up structure 25.

FIG. 1B shows a prior art carrier substrate.

FIG. 1B shows an independent carrier substrate 30 needs to be prepared and then attached on to the solder balls 4 of FIG. 1A. The carrier substrate 30 has a plurality of top metal pad 301 fabricated matching IC design rule; and the carrier substrate 30 has a plurality of bottom metal pad 302 fabricated matching PCB design rule.

The prior art discloses an IC package which is prepared until when the structure of FIG. 1B combining with the structure FIG. 1A. The combining structure has a plurality of top metal pad 210 suitable for a chip or chips to mount, and the combining structure has a plurality of bottom solder ball 42 suitable for mounting itself onto an outside mother board.

The disadvantage for the prior art is that a complicated fabricating process is performed, for example, including but not limited to, the alignment of each and all interposers 20 onto an outside carrier before further processing, the applying of the molding layer 22 for wrapping around the four lateral sides of the embedded interposer 20 during the processing . . . etc. Further more, an independent carrier substrate 30 needs to be prepared separately in a PCB process and is then to mount on a bottom side of the solder ball 4. A plurality of solder ball 42 is configured on a bottom side of the carrier substrate 30. The solder ball 42 is made according to PCB design rule so that the whole IC package can then be mounted onto an outside mother board.

A simplified process to reduce the cost and reduce the fabrication time for fabricating an IC package has been desired for a long time in the industry.

### BRIEF DESCRIPTION OF THE DRAWINGS

FIG. 1A shows a prior art IC package

FIG. 1B shows a prior art carrier substrate

FIG. 2A shows a first embodiment according to the present invention

FIG. 2B shows a second embodiment according to the present invention

FIGS. 3-6 and FIG. 7A show a fabricating process for the first embodiment according to the present invention

FIGS. 3-6 and FIGS. 7B-14 show a fabricating process for the second embodiment according to the present invention

FIG. 15 shows a single package unit of the second embodiment after dicing according to the present invention

FIG. 16 shows a top view of FIG. 14 before cutting

FIG. 17 shows a bottom view of FIG. 14 before cutting

FIG. 18 shows a fabricating process for the first embodiment according to the present invention

FIG. 19 shows a fabricating process for the second embodiment according to the present invention

FIGS. 20A-20B show a third and a fourth embodiment according to the present invention

FIG. 21 shows a fabricating process for the third embodiment according to the present invention

FIG. 22 shows a fabricating process for the fourth embodiment according to the present invention

### DETAILED DESCRIPTION OF THE INVENTION

The present invention discloses a high density IC package with a core substrate for a plurality of via metal to lodge in. The core substrate has four lateral sides; each lateral side has an edge flushed with a corresponding lateral side edge of the package. A bottom first redistribution circuit is configured on a bottom side of the core substrate, and a bottom second redistribution circuit is configured on a bottom side of the bottom first redistribution circuit.

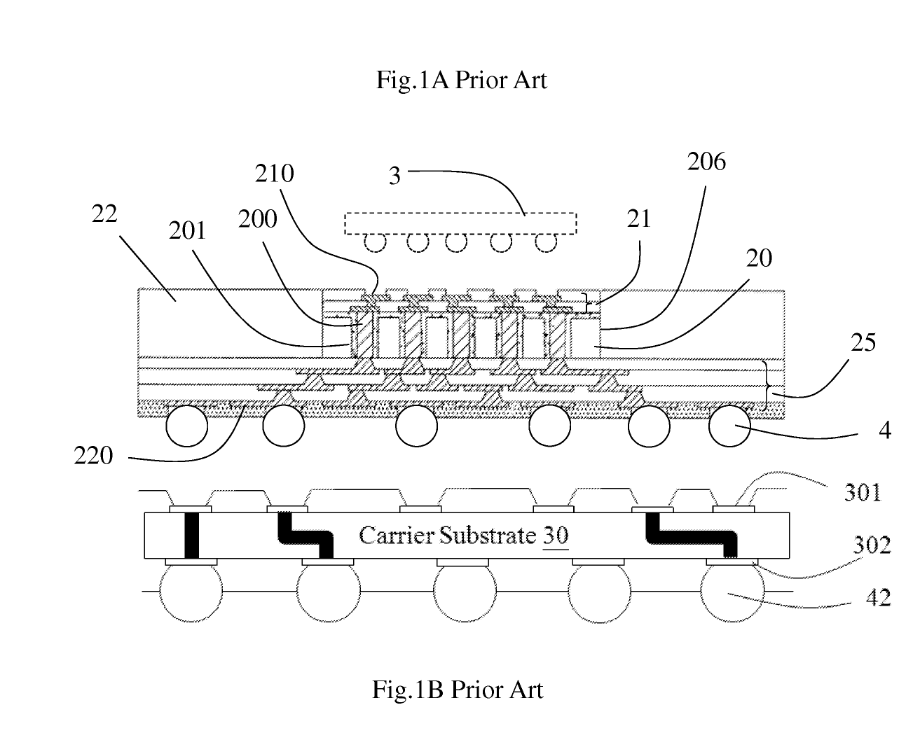

When the core substrate used in this invention is a silicon substrate, an insulation liner 5011, like the one the insulation liner 201 shown in FIG. 1A, needs to be formed between the silicon substrate and the electric circuits as well as formed between the silicon substrate and the via metal, because the silicon substrate is somewhat electrically conductive which is selected from one of either N-substrate or P-substrate.

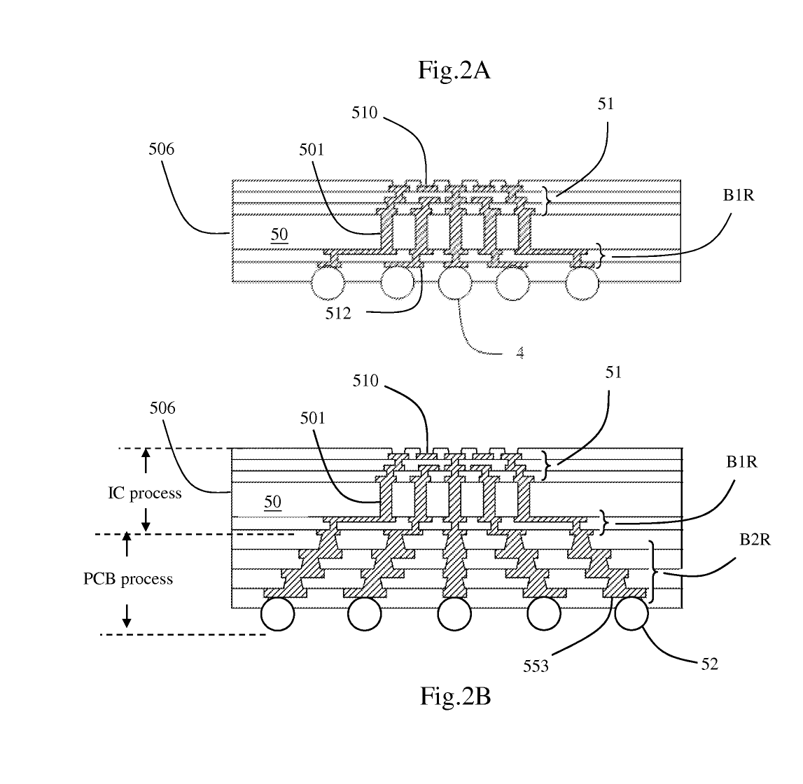

FIG. 2A shows a first embodiment according to the present invention

FIG. 2A shows a single package having a plurality of top metal pad 510 suitable for a chip or chips to mount, and having a plurality of bottom solder ball 4 suitable for mounting it onto an intermediate carrier substrate 30 before itself can be mounted to an outside mother board. FIG. 2A has a core substrate 50 configured in the middle layer in thickness direction. The core substrate 50 has four later sides 506; each of the lateral side 506 is flushed with a corresponding lateral side of the package. A plurality of via metal 501 is made passing through the core substrate 50. A top redistribution circuit 51 is fabricated on a top side of the core substrate 50, with a plurality of top metal pad 510 exposed on a top side of the package. A bottom first redistribution circuit B1R is fabricated on a bottom side of the core substrate 50 with a plurality of bottom metal pad 512 exposed on a bottom side of bottom first redistribution circuit B1R. A plurality of solder ball 4, each is configured on a bottom side of a corresponding bottom pad 512. FIG. 2A forms a package functioning equivalent to the structure of FIG. 1A, however FIG. 1A is not suitable for mounting itself directly onto an outside mother board due to the plurality solder ball 4 prepared under IC design rule, for which, the pitch of the solder ball 4 does not match PCB design rule.

FIG. 2B shows a second embodiment according to the present invention

FIG. 2B shows that a core substrate 50 has four lateral sides 506 extended to each corresponding lateral side of the package unit. A plurality of via metal 501 is made passing through the core substrate 50. A top redistribution circuit 51 is fabricated following a first design rule such as IC design rule or TFTLCD design rule, configured on a top side of the core substrate 50 with a plurality of top metal pad 510 exposed on a top side of the package unit. A bottom first redistribution circuit B1R is fabricated following a first design rule, configured on a bottom side of the core substrate 50; and a bottom second redistribution circuit B2R, fabricated following a second design rule such a PCB design rule, configured on a bottom side of the bottom first redistribution circuit B1R with a plurality of bottom metal pad 553 exposed on a bottom side of the package unit. A plurality of solder ball 52, each is configured on a bottom side of a corresponding bottom pad 553.

Generally, an IC design rule or TFTLCD design rule has a dimension in a scale of micrometer (um) to nanometer (nm), and a PCB design rule has a dimension in a scale around tenth of micrometer (um). The bottom first redistribution circuit B1R is designed to fan out a circuit density of the via metal 501; and the bottom second redistribution B2R circuit is designed to fan out a circuit density of the bottom first redistribution circuit B1R.

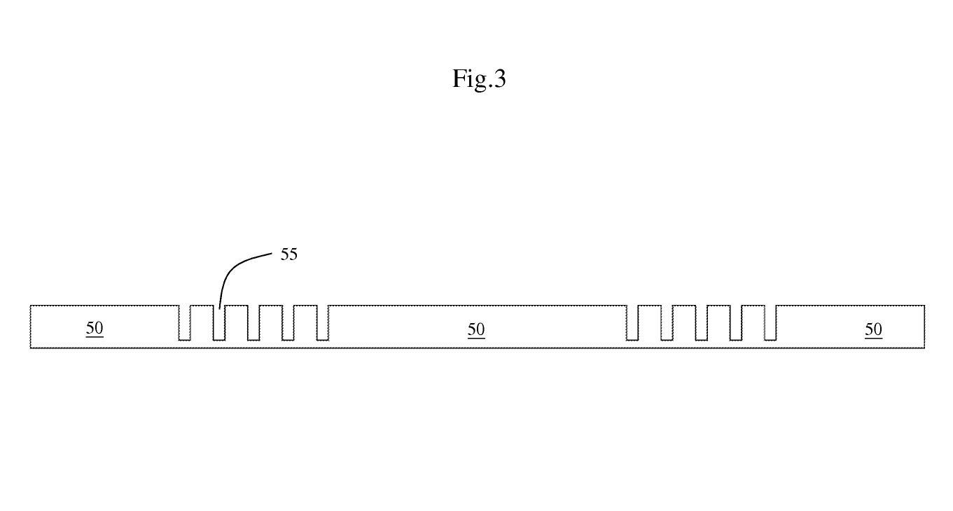

FIGS. 3-6 and FIG. 7A show a fabricating process for the first embodiment according to the present invention.

For simplification, two package units are illustrated for a mass production according to the present invention.

FIG. 3 shows a core substrate 50 is prepared and a plurality of hole 55 is formed from top side of the core substrate 50.

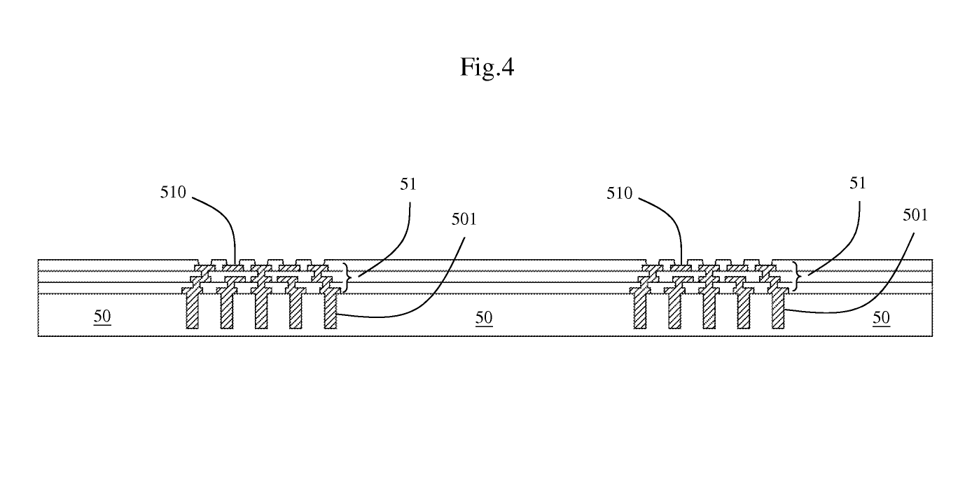

FIG. 4 shows via metals 501 are formed and top redistribution circuit 51 is formed through conventional build-up technique. A plurality of metal pad 510 is exposed on a top side of the package unit.

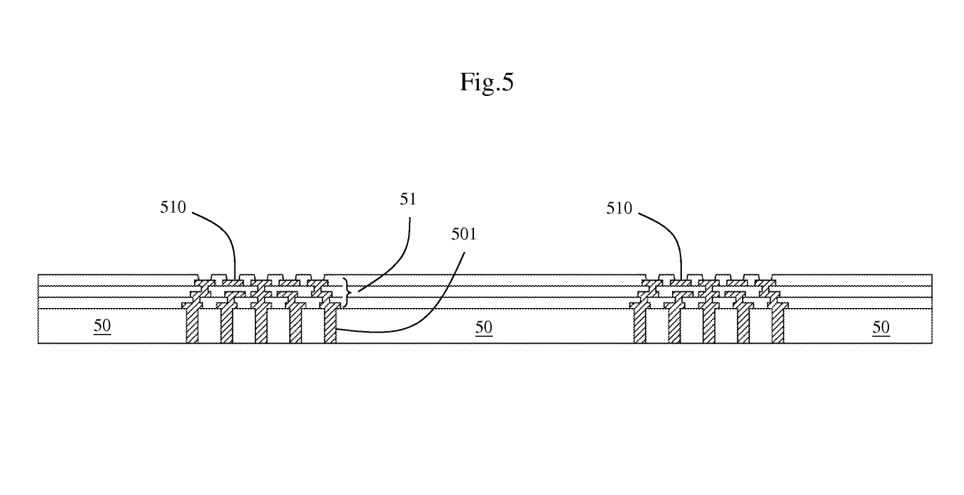

FIG. 5 shows substrate removal from the bottom side of the core substrate 50 to reveal a bottom end of each via metal 501 through conventional technique such as grinding or chemical-mechanical-polishing (CMP).

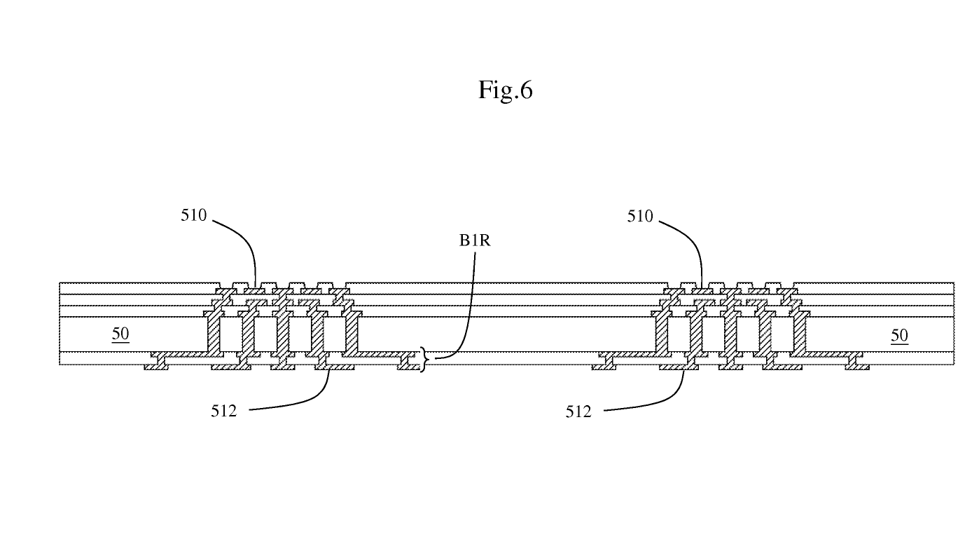

FIG. 6 shows a bottom first redistribution circuit B1R is formed on a bottom side of the core substrate 50 through conventional build-up technique. The bottom first redistribution circuit B1R is fabricated following IC design rule or TFTLCD design rule. A plurality of metal pad 512 is exposed on a bottom side of the package unit.

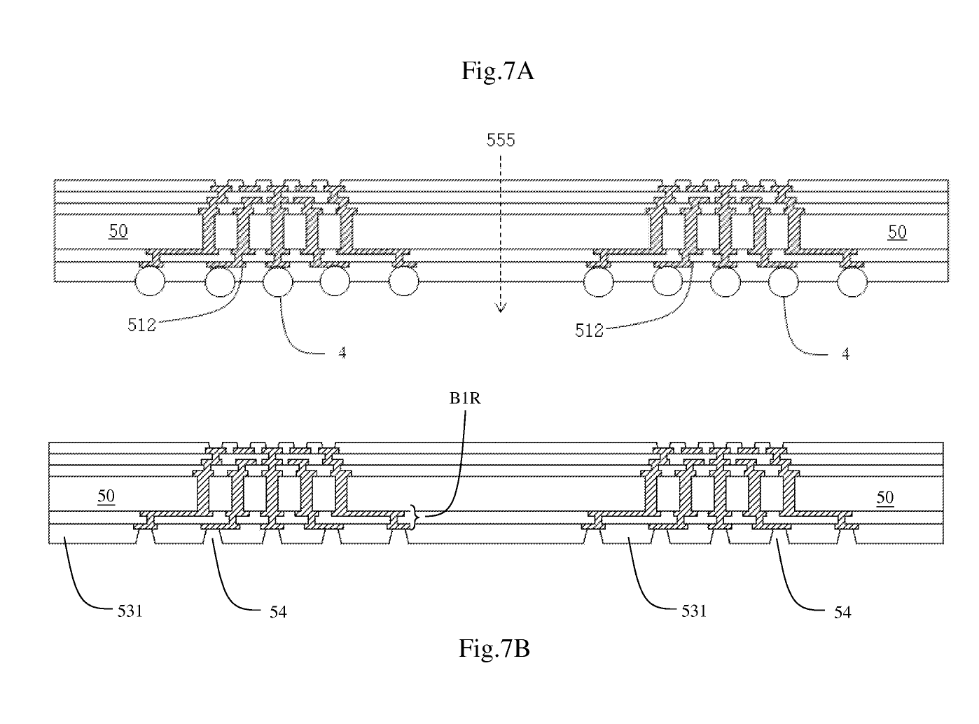

FIG. 7A shows a plurality of solder ball 4, each is configured on a bottom side of a corresponding metal pad 512. The structure of FIG. 7A is then dicing along the dicing line 555 to yield a plurality of single package unit of the first embodiment.

FIGS. 3-6 and FIGS. 7B-14 show a fabricating process for the second embodiment according to the present invention

FIGS. 3-6 are the same as described above, and omitted here for simplification.

FIGS. 7B-14 show a process to fabricating a bottom second redistribution circuit B2R on a bottom side of the bottom first redistribution circuit B1R.

FIG. 7B shows a first dielectric layer 531 covers on a bottom side of the bottom pad 512, and a plurality of hole 54 is made to reveal each metal pad 512. The dielectric layer used for the bottom second redistribution circuit can be one of Ajinomoto build-up films (ABF) or Pre-preg (PP).

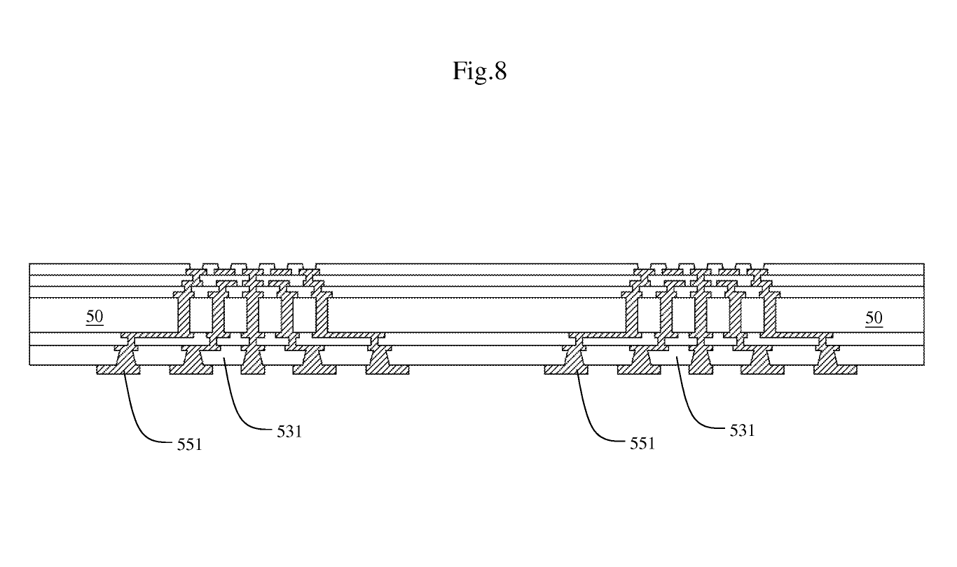

FIG. 8 shows metal filled in each hole 54 and a plurality of metal pad 551 is formed.

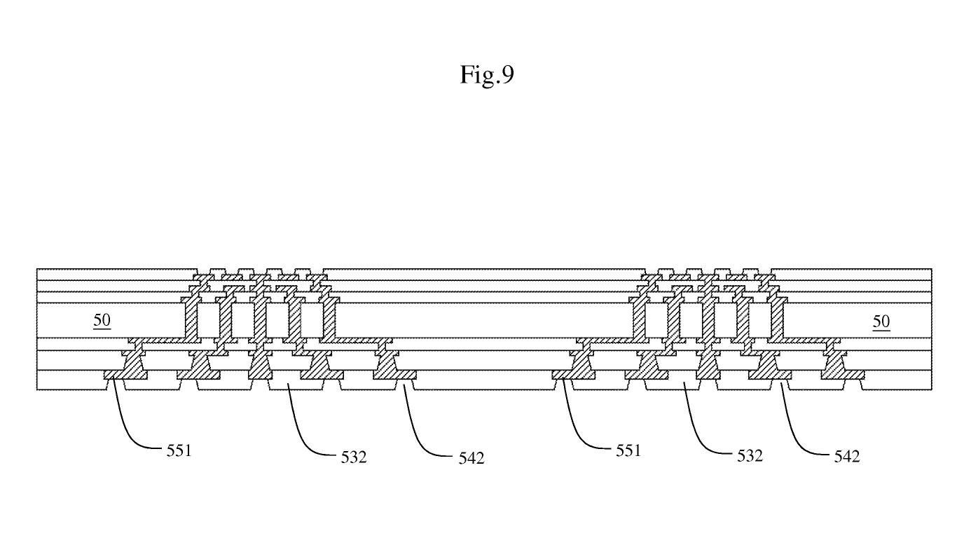

FIG. 9 shows a second dielectric layer 532 covers on a bottom side of the bottom pad 551, and a plurality of hole 542 is made to reveal each metal pad 551.

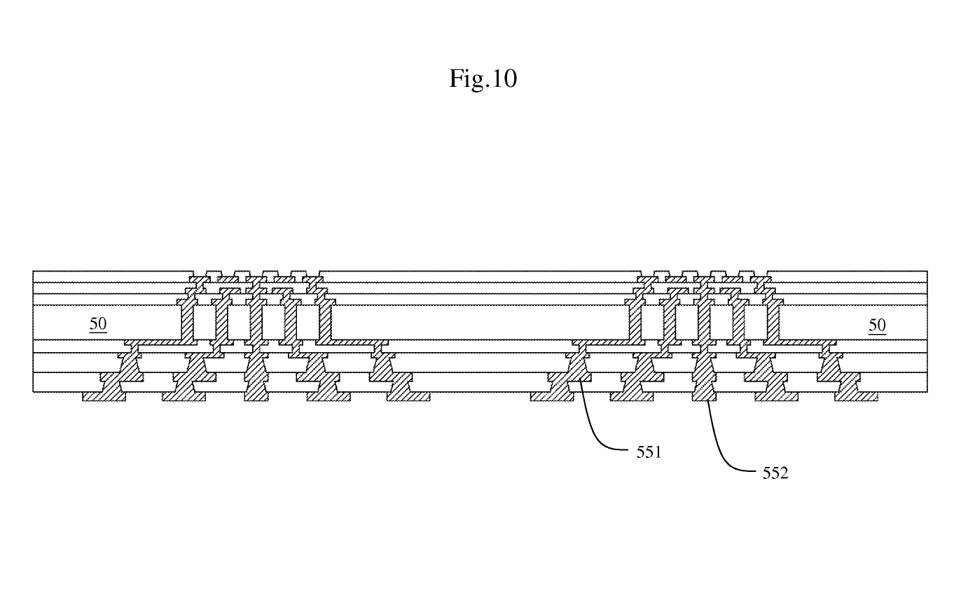

FIG. 10 shows metal filled in each hole 542 and a plurality of metal pad 552 is formed.

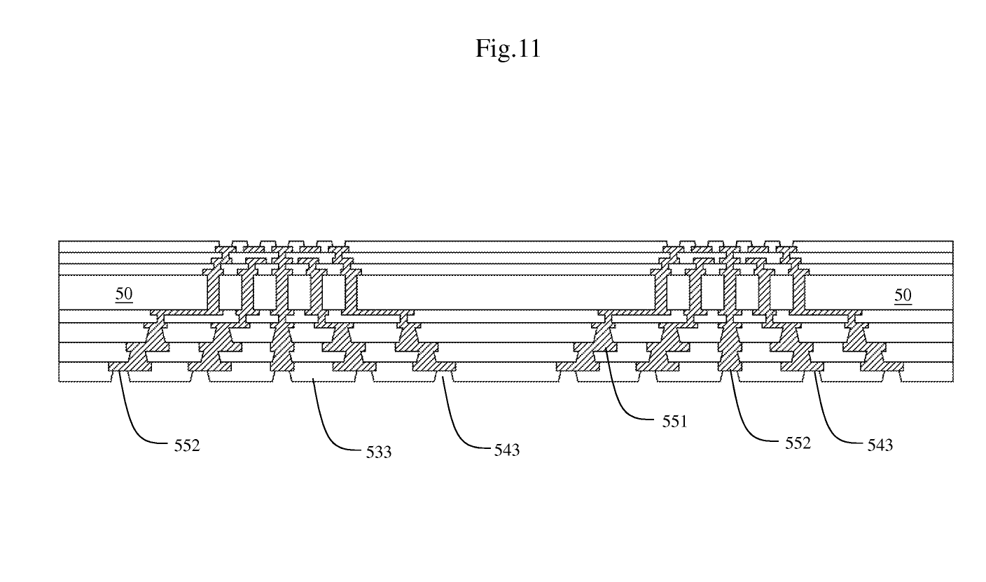

FIG. 11 shows a third dielectric layer 533 covers on a bottom side of the bottom pad 552, and a plurality of hole 543 is made to reveal each metal pad 552.

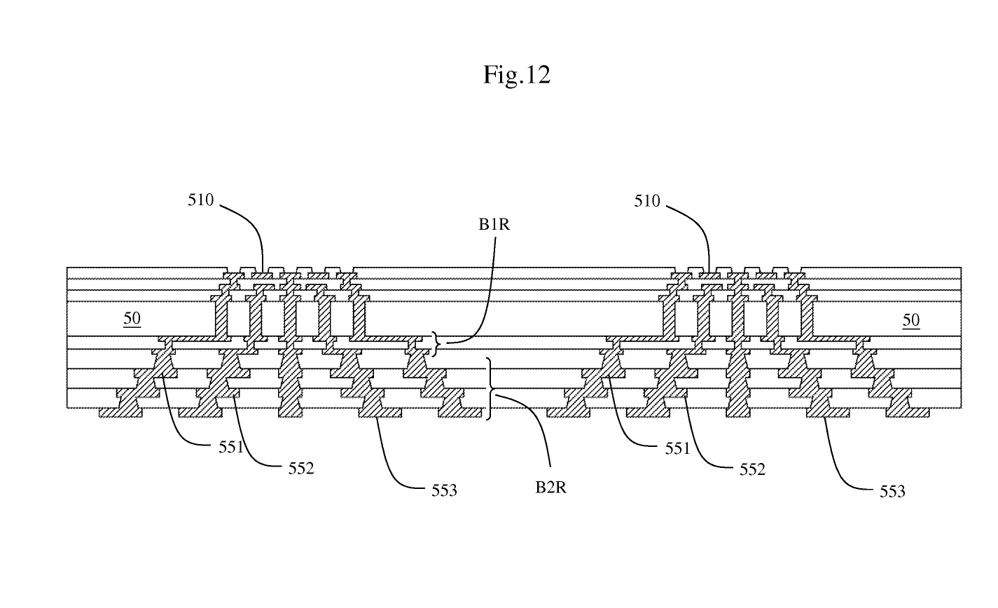

FIG. 12 shows metal filled in each hole 543 and a plurality of metal pad 553 is formed.

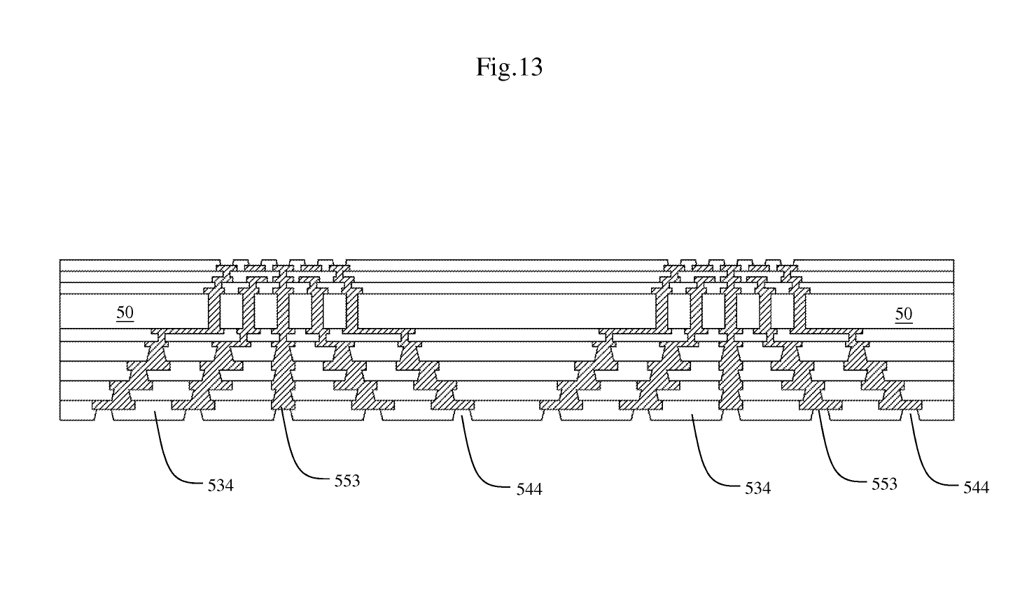

FIG. 13 shows a fourth dielectric layer 534 covers on a bottom side of the bottom pad 553, and a plurality of hole 544 is made to reveal each metal pad 553.

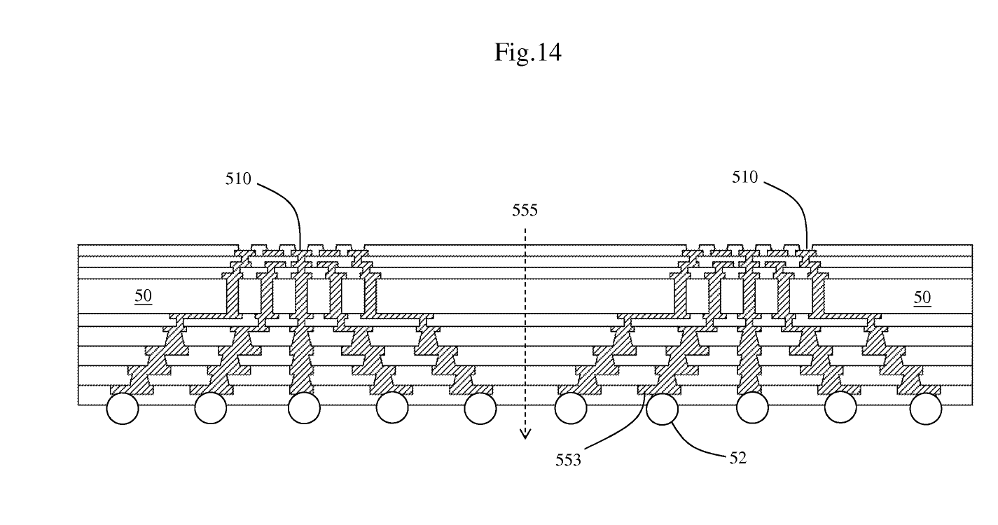

FIG. 14 shows a plurality of solder ball 52, each is configured on a bottom side of each corresponding bottom pad 553. A dicing line 555 is shown in the middle of the two package units before cutting.

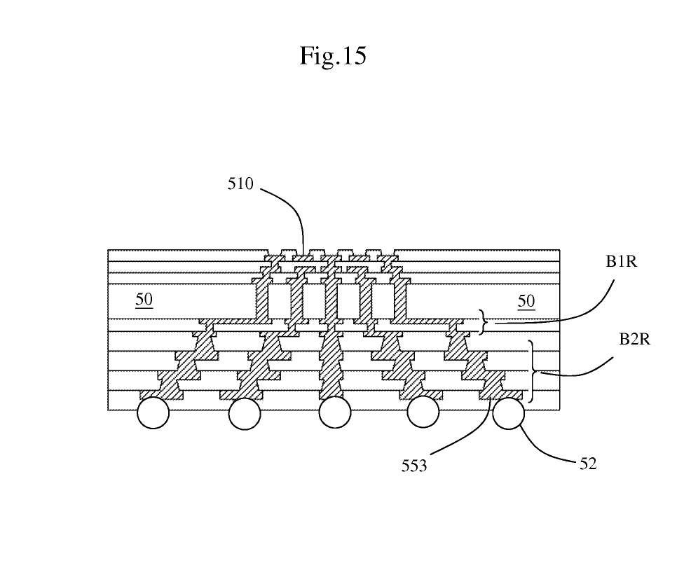

FIG. 15 shows a single package unit of the second embodiment after dicing according to the present invention.

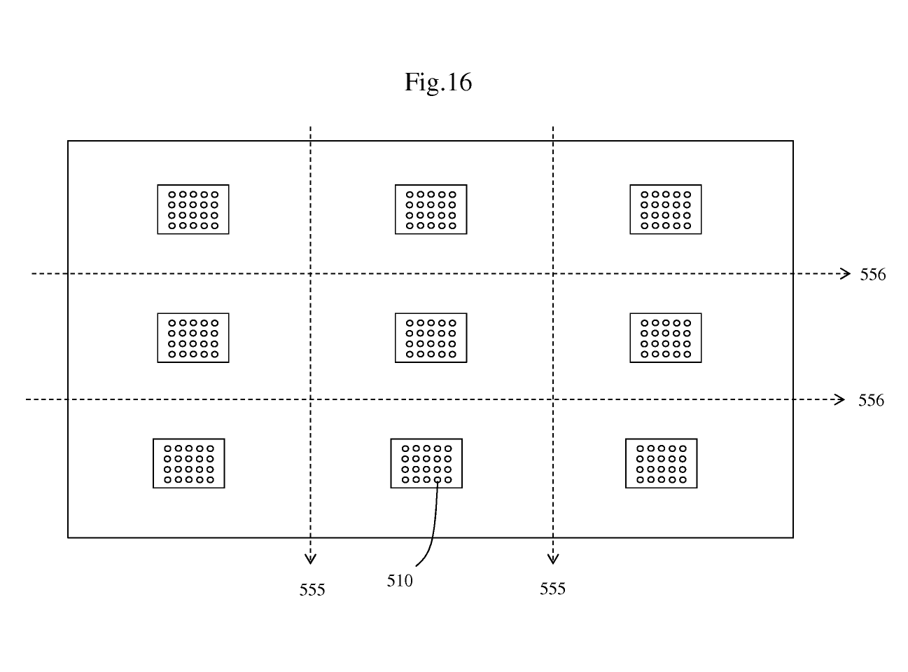

FIG. 16 shows a top view of FIG. 14 before cutting.

A 3*3 package unit is illustrated in a mass production according to the present invention. A plurality of top pad 510 is shown from a top view of the package before cutting. A plurality of vertical dicing line 555 and a plurality of horizontal dicing line 556 are shown. A plurality of package unit of the second embodiment can be yield after dicing along the dicing lines 555, 556.

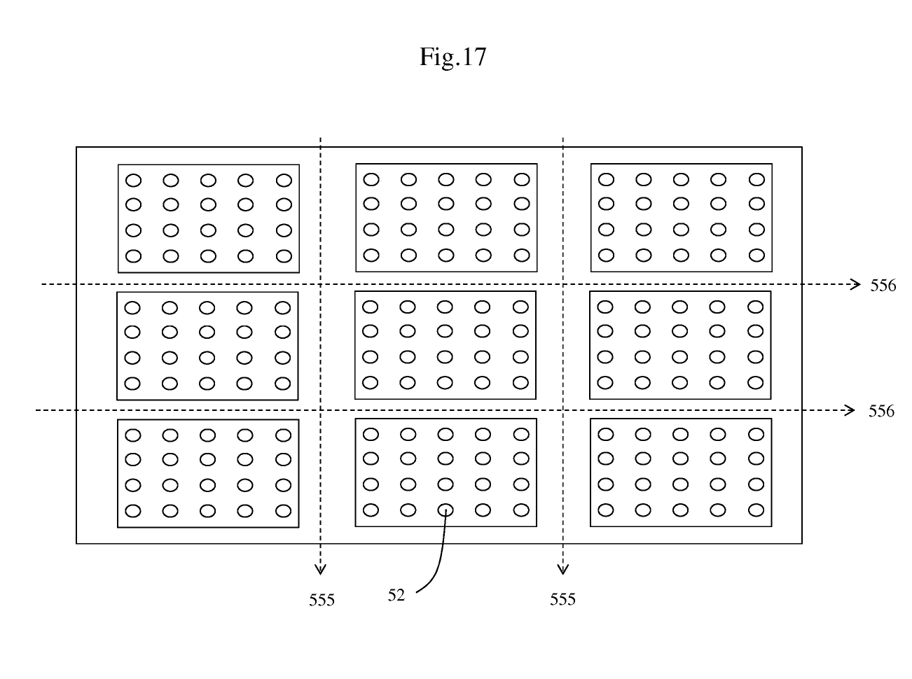

FIG. 17 shows a bottom view of FIG. 14 before cutting

A plurality of solder ball 52 is shown from a bottom view of the package before cutting. A plurality of vertical dicing line 555 and a plurality of horizontal dicing line 556 are shown. A plurality of package unit of the second embodiment is produced after dicing along the dicing lines 555, 556.

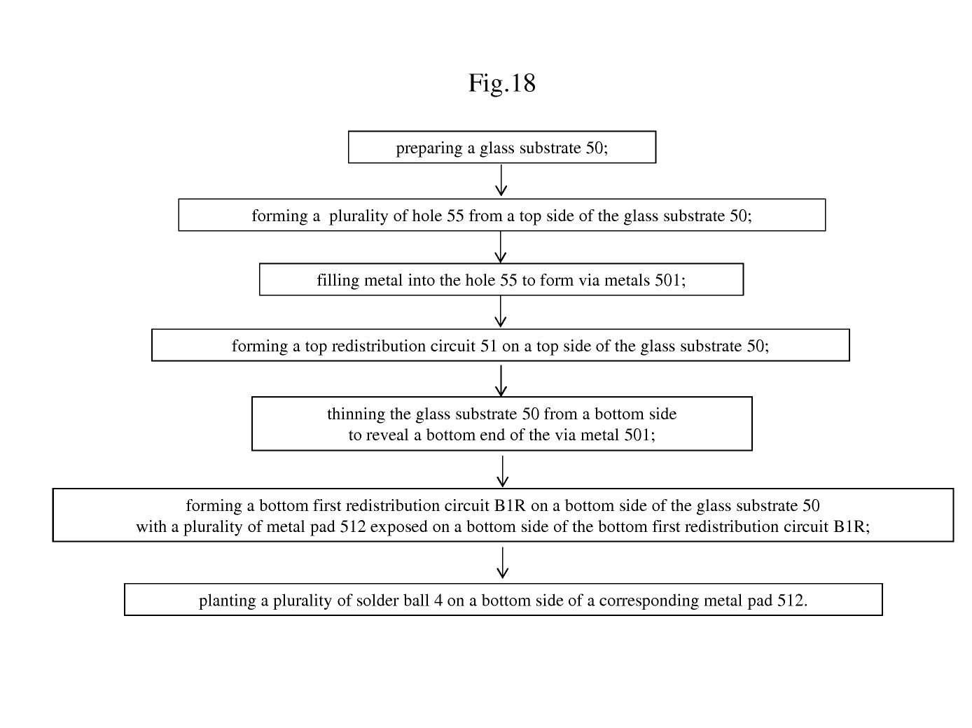

FIG. 18 shows a fabricating process for the first embodiment according to the present invention

preparing a core substrate 50;

forming a plurality of hole 55 from a top side of the core substrate 50;

filling metal into the hole to form via metals 501;

forming a top redistribution circuit 51 on a top side of the core substrate 50;

thinning the core substrate 50 from a bottom side to reveal a bottom end of the via metals 501;

forming a bottom first redistribution circuit B1R on a bottom side of the core substrate 50 with a plurality of metal pad 512 exposed on a bottom side of the package unit; and

planting a plurality of solder ball 52 on a bottom side of each corresponding metal pad 512.

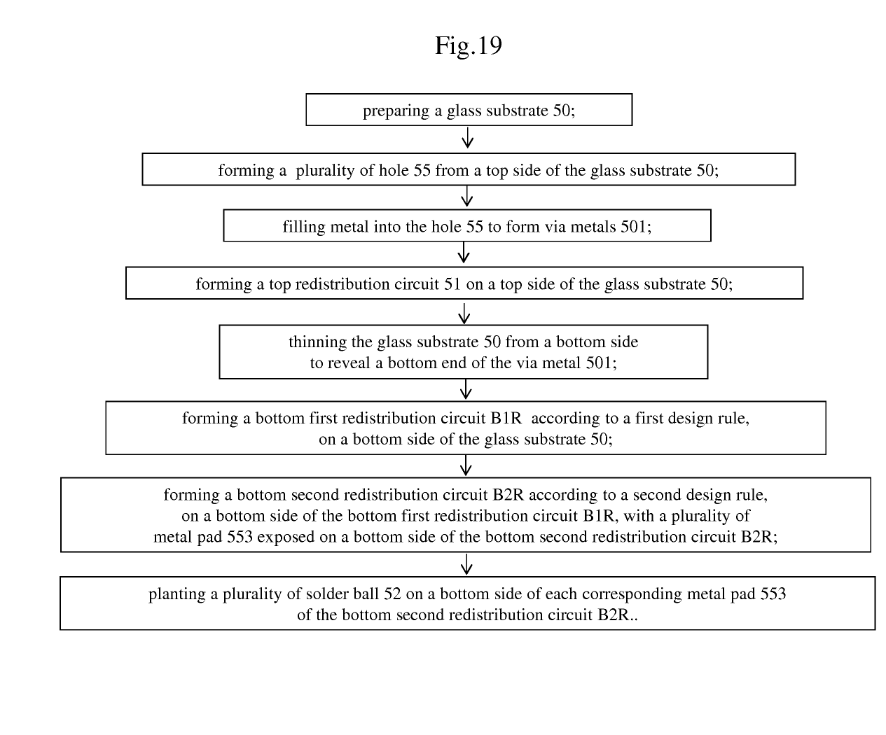

FIG. 19 shows a fabricating process for the second embodiment according to the present invention

preparing a core substrate 50;

forming a plurality of hole 55 from a top side of the core substrate 50;

filling metal into the hole to form via metals 501;

forming a top redistribution circuit 51 on a top side of the core substrate 50;

thinning the core substrate 50 from a bottom side to reveal a bottom end of the via metals 501;

forming a bottom first redistribution circuit B1R according to a first design rule, on a bottom side of the core substrate 50; and

forming a bottom second redistribution B2R circuit according to a second design rule, on a bottom side of the bottom first redistribution circuit B1R with a plurality of metal pad 502 exposed on a bottom side of the package unit; and

planting a plurality of solder ball 52 on a bottom side of each corresponding metal pad 502.

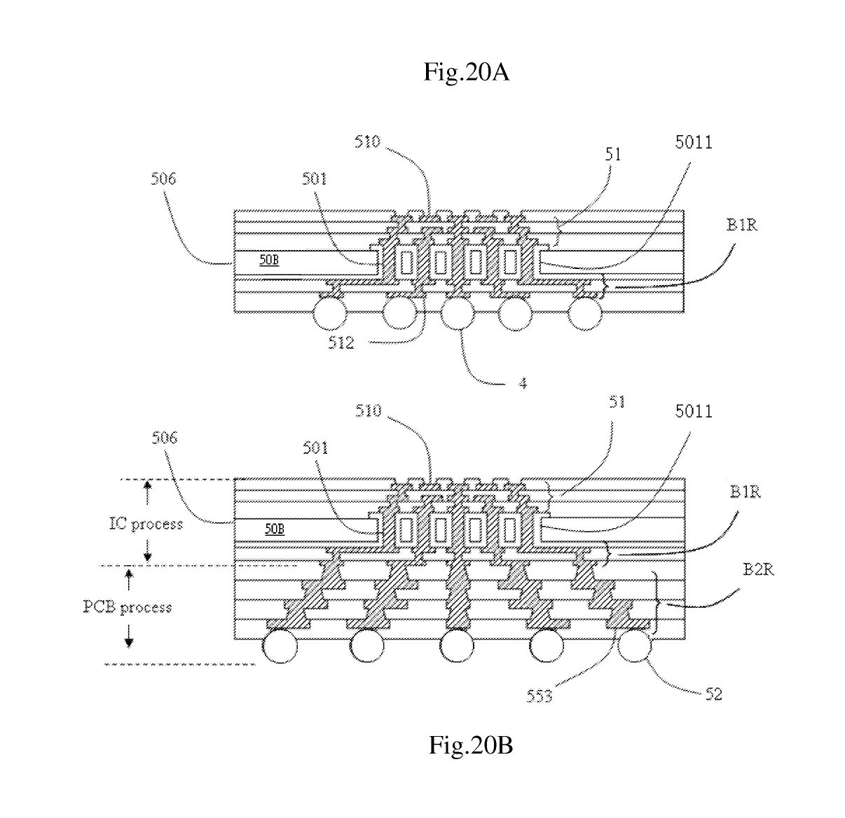

FIGS. 20A-20B show a third and a fourth embodiment according to the present invention

FIG. 20A shows a third embodiment similar to the one of FIG. 2A. The only difference is that an insulation liner 5011 is formed between the silicon substrate 50B and the circuits, as well as formed between the silicon substrate 50B and the via metal 501.

FIG. 20B shows a fourth embodiment similar to the one of FIG. 2B. The only difference is that an insulation liner 5011 is formed between the silicon substrate 50B and the circuits, as well as formed between the silicon substrate 50B and the via metal 501.

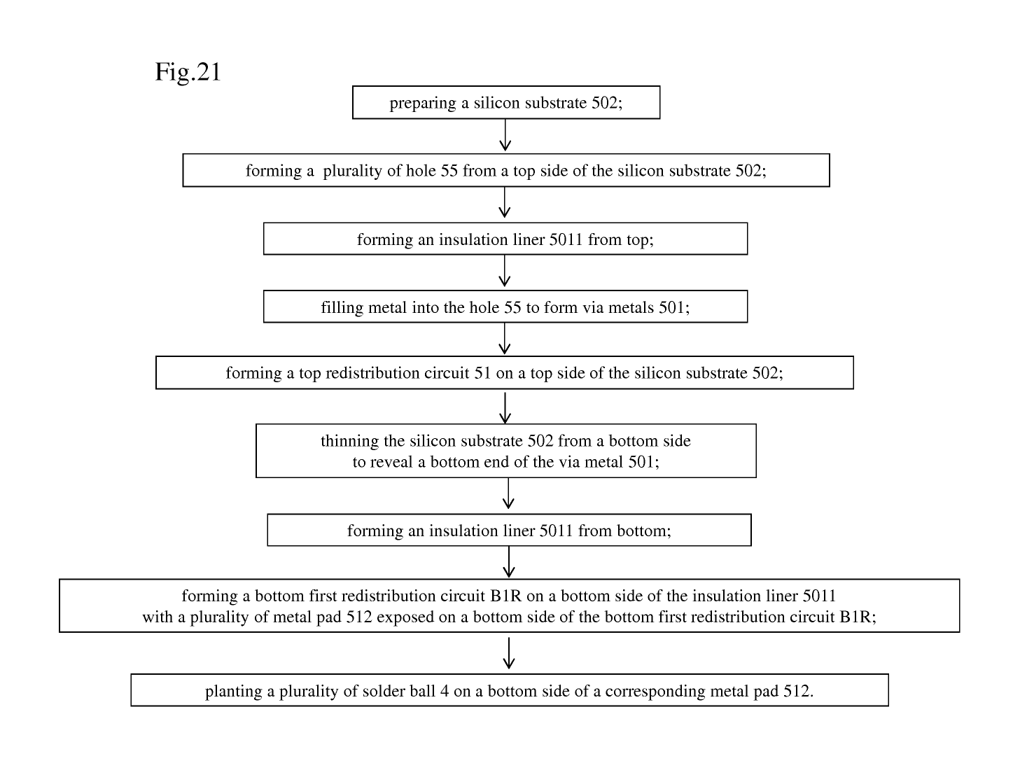

FIG. 21 shows a fabricating process for the third embodiment according to the present invention

preparing a silicon substrate 50B;

forming a plurality of hole 55 from a top side of the silicon substrate 50B;

forming an insulation liner 5011 from top to cover on a wall surface of the hole 55 and on a top surface of the silicon substrate 50B;

filling metal into the hole to form via metals 501;

forming a top redistribution circuit 51 on a top side of the silicon substrate 50B;

thinning the silicon substrate 50B from a bottom side to reveal a bottom end of the via metals 501;

forming an insulation liner 5011 from bottom to cover on a bottom surface of the silicon substrate 50B;

forming a bottom first redistribution circuit B1R on a bottom side of the insulation liner 5011 with a plurality of metal pad 512 exposed on a bottom side of the package unit; and

planting a plurality of solder ball 52 on a bottom side of each corresponding metal pad 512.

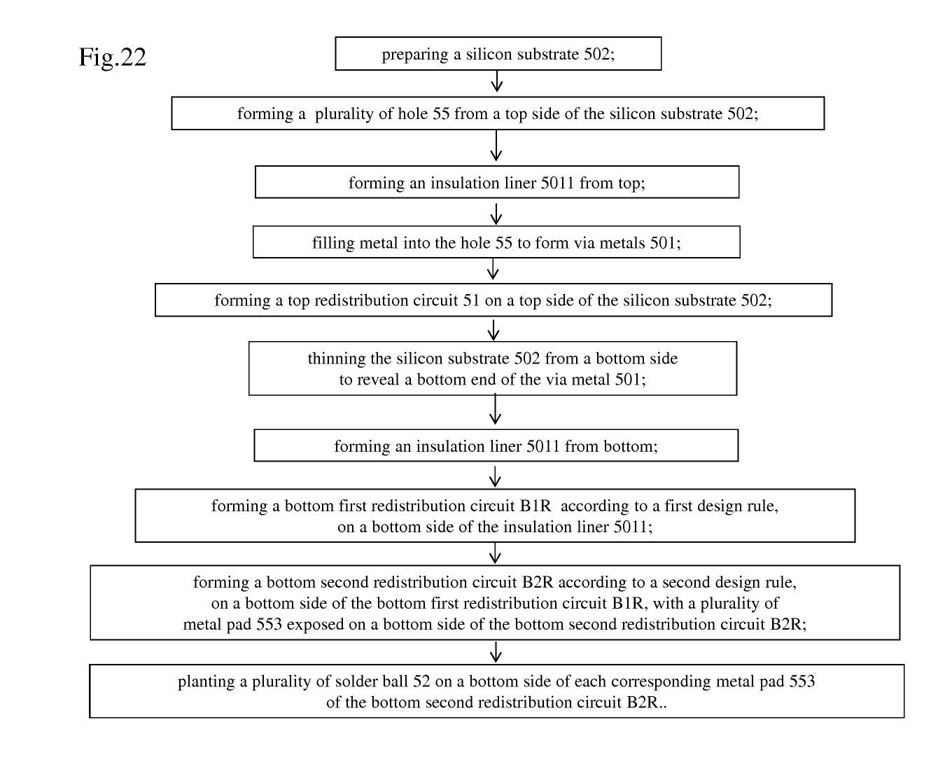

FIG. 22 shows a fabricating process for the fourth embodiment according to the present invention

preparing a silicon substrate 50B;

forming a plurality of hole 55 from a top side of the silicon substrate 50B;

forming an insulation liner 5011 from top to cover on a wall surface of the hole 55 and on a top surface of the silicon substrate 50B;

filling metal into the hole to form via metals 501;

forming a top redistribution circuit 51 on a top side of the silicon substrate 50B;

thinning the silicon substrate 50B from a bottom side to reveal a bottom end of the via metals 501;

forming an insulation liner 5011 from bottom to cover on a bottom surface of the silicon substrate 50B;

forming a bottom first redistribution circuit B1R according to a first design rule, on a bottom side of the insulation liner 5011; and

forming a bottom second redistribution B2R circuit according to a second design rule, on a bottom side of the bottom first redistribution circuit B1R with a plurality of metal pad 502 exposed on a bottom side of the package unit; and

planting a plurality of solder ball 52 on a bottom side of each corresponding metal pad 502.

While several embodiments have been described by way of example, it will be apparent to those skilled in the art that various modifications may be configured without departs from the spirit of the present invention. Such modifications are all within the scope of the present invention, as defined by the appended claims.

1. A high density IC package, comprising:
a core substrate, having four lateral sides each extended to a corresponding lateral side of the package;
a plurality of metal vias passing through the core substrate;
a top redistribution circuit fabricated according to a first design rule, the top redistribution circuit configured on a top side of the core substrate and having a plurality of top metal pads exposed on a top side of the top redistribution circuit; and
a bottom first redistribution circuit fabricated according to the first design rule, the bottom first redistribution circuit configured on a bottom side of the core substrate and having a plurality of first bottom metal pads on a bottom side of the bottom first redistribution circuit,
wherein
the top redistribution circuit is configured to upwardly fan in, layer by layer, a circuit density of the metal vias, and
the bottom first redistribution circuit is configured to downwardly fan out, layer by layer, the circuit density of the metal vias.

2. A high density IC package as claimed in claim 1, further comprising:
a plurality of solder balls, each attached to a bottom surface of a corresponding one of the first bottom metal pads.

3. A high density IC package as claimed in claim 1, further comprising:
a bottom second redistribution circuit fabricated according to a second design rule, the bottom second redistribution circuit configured on the bottom side of the bottom first redistribution circuit and having a plurality of second bottom metal pads on a bottom side of the bottom second redistribution circuit,
wherein
the bottom second redistribution circuit is configured to further downwardly fan out, layer by layer, a circuit density of the bottom first redistribution circuit.

4. A high density IC package as claimed in claim 1, wherein the first design rule is selected from the group consisting of IC design rule and TFTLCD design rule.

5. A high density IC package as claimed in claim 3, wherein
the first design rule is selected from the group consisting of IC design rule and TFTLCD design rule, and
the second design rule is PCB design rule.

6. A high density IC package as claimed in claim 1, wherein the first design rule has a dimension in a scale of micrometer (um) to nanometer (nm).

7. A high density IC package as claimed in claim 3, wherein
the first design rule has a dimension in a scale of micrometer (um) to nanometer (nm), and
the second design rule has a dimension in a scale around tenth of millimeter.

8-9. (canceled)

10. A high density IC package as claimed in claim 1, wherein the core substrate is an organic substrate selected from the group consisting of Polyimide (PI), Polybenzoxazole (PBO), and Benzocyclobuten (BCB).

11. A high density IC package as claimed in claim 1, wherein the core substrate is an inorganic substrate selected from the group consisting of glass substrate and ceramic substrate.

12. A high density IC package as claimed in claim 1, wherein the core substrate is a silicon substrate, the IC package further comprising:
an insulation liner configured between the silicon substrate and the metal vias.

13. A process for fabricating an IC package, the process comprising:
forming a plurality of holes in a core substrate;
filling metal into the holes to form metal vias in the core substrate;
forming a top redistribution circuit according to a first design rule on a top side of the core substrate, the top redistribution circuit having a plurality of top metal pads exposed on a top side of the top redistribution circuit;
thinning the core substrate from a bottom side to expose bottom ends of the metal vias; and
forming a bottom first redistribution circuit according to the first design rule on the bottom side of the core substrate, the bottom first redistribution circuit having a plurality of first bottom metal pads exposed on a bottom side of the bottom first redistribution circuit,
wherein
the top redistribution circuit is configured to upwardly fan in, layer by layer, a circuit density of the metal vias, and
the bottom first redistribution circuit is configured to downwardly fan out, layer by layer, the circuit density of the metal vias.

14. A process for fabricating a high density IC package as claimed in claim 13, further comprising:
planting a plurality of solder balls each on a bottom surface of a corresponding one of the first bottom metal pads.

15. A process for fabricating a high density IC package as claimed in claim 13, further comprising:
forming a bottom second redistribution circuit according to a second design rule on the bottom side of the bottom first redistribution circuit, the bottom second redistribution circuit having a plurality of second bottom metal pads exposed on a bottom side of the bottom second redistribution circuit,
wherein
the bottom second redistribution circuit is configured to further downwardly fan out, layer by layer, a circuit density of the bottom first redistribution circuit.

16. A process for fabricating a high density IC package as claimed in claim 13, wherein the first design rule is selected from the group consisting of IC design rule and TFTLCD design rule.

17. A process for fabricating a high density IC package as claimed in claim 15, wherein
the first design rule is selected from the group consisting of IC design rule and TFTLCD design rule, and
the second design rule is PCB design rule.

18. A process for fabricating a high density IC package as claimed in claim 13, wherein the first design rule has a dimension in a scale of micrometer (um) to nanometer (nm).

19. A process for fabricating a high density IC package as claimed in claim 15, wherein
the first design rule has a dimension in a scale of micrometer (um) to nanometer (nm), and
the second design rule has a dimension in a scale around tenth of millimeter.

20. A process for fabricating a high density IC package as claimed in claim 15, further comprising:
planting a plurality of solder balls each on a bottom surface of a corresponding one of the second bottom metal pads of the bottom second redistribution circuit.

21. A process for fabricating a high density IC package as claimed in claim 15, wherein the core substrate is an organic substrate selected from the group consisting of Polyimide (PI), Polybenzoxazole (PBO), and Benzocyclobuten (BCB).

22. A process for fabricating a high density IC package as claimed in claim 15, wherein the core substrate is an inorganic substrate selected from the group consisting of glass substrate and ceramic substrate.

23. A process for fabricating a high density IC package as claimed in claim 13, wherein the core substrate is a silicon substrate, the process further comprising:
forming an insulation liner on a wall surface of each of the holes and on a top surface of the silicon substrate after said forming the plurality of holes.

24. A process for fabricating an IC package as claimed in claim 13, further comprising:
forming an insulation liner from the top side of the core substrate before said filling the metal into the holes to form the metal vias; and
forming an insulation liner from the bottom side of the core substrate before said forming the bottom first redistribution circuit.

25-34. (canceled)

35. A high density IC package as claimed in claim 1, further comprising:
an insulation liner configured between the core substrate and the metal vias.

36. A high density IC package as claimed in claim 35, wherein the insulation liner is further on the top side of the core substrate, and configured between the top side of the core substrate and the top redistribution circuit.

37. (canceled)

38. A high density IC package as claimed in claim 36, wherein the insulation liner is further on the bottom side of the core substrate, and configured between the bottom side of the core substrate and the bottom first redistribution circuit.

39. A high density IC package as claimed in claim 38, further comprising:
a bottom second redistribution circuit fabricated according to a second design rule, the bottom second redistribution circuit configured on the bottom side of the bottom first redistribution circuit and having a plurality of second bottom metal pads on a bottom side of the IC package,
wherein
the bottom second redistribution circuit is configured to further downwardly fan out, layer by layer, a circuit density of the bottom first redistribution circuit.

40. A high density IC package as claimed in claim 39, wherein
the first design rule is selected from the group consisting of IC design rule and TFTLCD design rule, and
the second design rule is PCB design rule.

41. A high density IC package as claimed in claim 39, wherein
the first design rule has a dimension in a scale of micrometer (um) to nanometer (nm), and
the second design rule has a dimension in a scale around tenth of millimeter.

42-44. (canceled)

45. A high density IC package as claimed in claim 3, wherein
a total thickness of both the bottom first redistribution circuit and the bottom second redistribution circuit on the bottom side of the core substrate is greater than a thickness of the top redistribution circuit on the top side of the core substrate.

46. A high density IC package as claimed in claim 45, wherein
the bottom first redistribution circuit comprises:
a plurality of bottom first conductive layers, and
a plurality of bottom first conductive vias coupling the bottom first conductive layers to each other,
the bottom second redistribution circuit comprises:
a plurality of bottom second conductive layers, and
a plurality of bottom second conductive vias coupling the bottom second conductive layers to each other, and
a thickness of each of the plurality of bottom first conductive layers is smaller than a thickness of each of the plurality of bottom second conductive layers.

47. A high density IC package, comprising:
a core substrate;
a plurality of metal vias passing through the core substrate;
a top redistribution circuit configured on a top side of the core substrate and having a plurality of top metal pads exposed on a top side of the top redistribution circuit;
a bottom first redistribution circuit configured on a bottom side of the core substrate and having a plurality of first bottom metal pads on a bottom side of the bottom first redistribution circuit; and
a bottom second redistribution circuit configured on the bottom side of the bottom first redistribution circuit and having a plurality of second bottom metal pads on a bottom side of the bottom second redistribution circuit,
wherein
the bottom first redistribution circuit comprises:
a plurality of bottom first conductive layers one of which is in direct and physical contact with bottom ends of the metal vias, and
a plurality of bottom first conductive vias coupling the bottom first conductive layers to each other,
the bottom second redistribution circuit comprises:
a plurality of bottom second conductive layers, and
a plurality of bottom second conductive vias coupling the bottom second conductive layers to each other, and
a thickness of each of the plurality of bottom first conductive layers is smaller than a thickness of each of the plurality of bottom second conductive layers.

48. A high density IC package as claimed in claim 47, wherein
the top redistribution circuit comprises:
a plurality of top conductive layers, and
a plurality of top conductive vias coupling the top conductive layers to each other,
a lowermost one among the top conductive layers is in direct and physical contact with top ends of the metal vias, and
a thickness of each of the top conductive layers is smaller than the thickness of each of the plurality of bottom second conductive layers.

49. A high density IC package as claimed in claim 48, wherein
the top redistribution circuit and the bottom first redistribution circuit are compliant with a first design rule, and
the bottom second redistribution circuit is not compliant with the first design rule.

50. A high density IC package as claimed in claim 48, wherein
the top redistribution circuit and the bottom first redistribution circuit are compliant with a same design rule selected from the group consisting of IC design rule and TFTLCD design rule, and the bottom second redistribution circuit is compliant with PCB design rule.
